(19) United States
(12) Patent Application Publication
(10) Pub. No.: US 2013/0143065 A1
(43) Pub. Date: Jun. 6, 2013

(54) METHOD FOR ELECTROMAGNETIC SHIELDING AND PRODUCT MADE BY SAME

(71) Applicant: DA-HUA CAO, Shenzhen City (CN)

(72) Inventor: DA-HUA CAO, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/441,307

(22) Filed: Apr. 6, 2012

(30) Foreign Application Priority Data
Dec. 3, 2011 (CN) 201110395481.7

(51) Int. Cl. H05K 9/00; C23C 14/20; C23C 14/35; B32B 15/04

(52) U.S. Cl. 428/624; 204/192.14

(57) ABSTRACT

A product includes a plastic substrate; and a metal composite layer deposited on the plastic substrate. The metal composite layer includes a plurality of first metal layers and a plurality of second metal layers, the first metal layers and the second metal layers are alternate with each other. The first metal layer is Cu layer, Ag layer or Li layer. The second metal layer is Ni layer. The method for manufacturing the product is also provided.

### BACKGROUND

1. Technical Field

The exemplary disclosure generally relates to a method for electromagnetic shielding and products made by the method.

2. Description of Related Art

Vacuum coating, chemical plating, and electroplating are commonly used to deposit cooper layers on plastic substrates, and stainless steel layers on the copper layers. However, the plastic substrate with poor electromagnetic shielding property is not acceptable.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary method for electromagnetic shielding and product made by the method. Moreover, in the drawings like reference numerals designate corresponding parts throughout the several views. Wherever possible, the same reference numbers are used throughout the drawings to refer to the same or like elements of an embodiment.

FIG. 1 illustrates a cross-sectional view of an exemplary embodiment of a product.

FIG. 2 is a schematic view of a vacuum sputtering coating machine for manufacturing the product in FIG. 1.

### DETAILED DESCRIPTION

An exemplary method for electromagnetic shielding may include at least the following steps:

A plastic substrate 11 is provided. The plastic substrate 11 may be housing of mobile phone, personal digital assistant (PDA), notebook computer, portable music player, GPS navigator, or digital camera.

The plastic substrate 11 can be sandblasted to improve the bonding force between the plastic substrate 11 and the layer will form on the plastic substrate 11. The sandblasting process uses “80#” type ceramic sand and the sandblasting pressure is set at about 0.8 MPa to about 1.2 MPa.

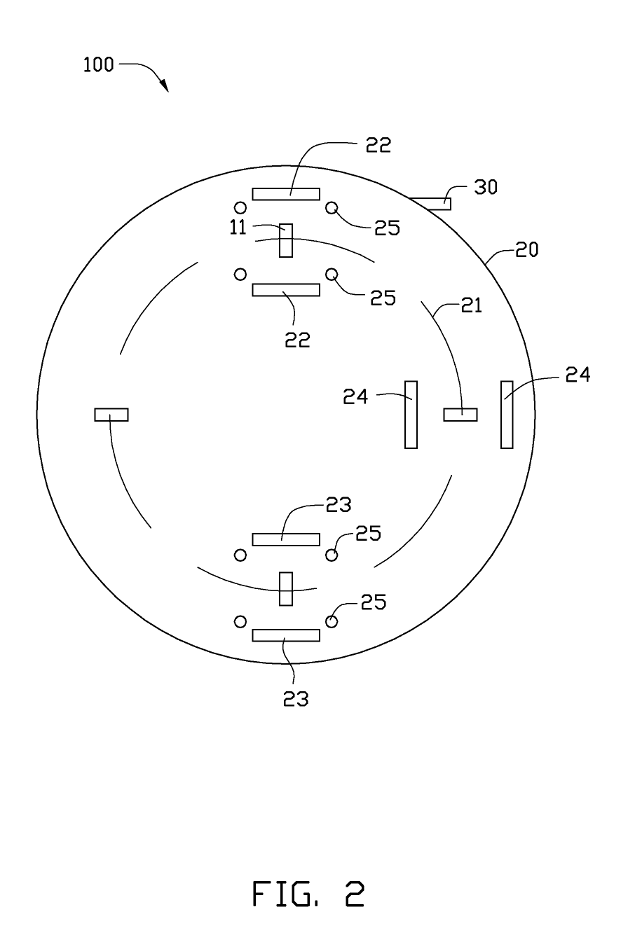

A vacuum sputtering coating machine 100 is provided. Referring to FIG. 2, the vacuum sputtering coating machine 100 includes a sputtering coating chamber 20 and a vacuum pump 30 connecting to the sputtering coating chamber 20. The vacuum pump 30 is used to pump air out of the sputtering coating chamber 20. The vacuum sputtering coating machine 100 further includes a rotating bracket 21, two first targets 22, two second targets 23, two third targets 24, and a plurality of gas inlets 25. The rotating bracket 21 rotates the plastic substrate 11 in the sputtering coating chamber 20 relative to the first targets 22, the second targets 23, and the third targets 24. The two first targets 22 face each other, and are located on opposite sides of the rotating bracket 21; the two second targets 23 face each other, and are located on opposite sides of the rotating bracket 21; the two third targets 24 face each other, and are located on opposite sides of the rotating bracket 21. In the exemplary embodiment, the first targets 22 are made of material selected from one of Cu, Ag and Li; the second targets 23 are made of Ni; the third targets 24 are made of material selected from one of stainless steel, Ni and Cr.

The metal composite layer 13 is deposited on the plastic substrate 11. The metal composite layer 13 may includes a plurality of first metal layers 131 alternating with an equal number of second metal layers 133. The first metal layer 131 can be Cu layer, Ag layer or Li layer. The second metal layer 133 is Ni layer. The plastic substrate 11 is retained on a rotating bracket 21 in a sputtering coating chamber 20. The vacuum level inside the sputtering coating chamber 20 is set to 4×10⁻³-6×10⁻³ Pa. The temperature in the sputtering coating chamber 20 is room temperature. Argon gas is fed into the sputtering coating chamber 20 at a flux rate about 150 Standard Cubic Centimeters per Minute (sccm) to about 240 sccm from the gas inlets 24. Sputtering the first targets 22 and the second targets 23 at the same time. The first targets 22 in the sputtering coating chamber 20 are evaporated at a power between about 8 kW and about 12 kW. The second targets 23 in the sputtering coating chamber 20 are evaporated at a power between about 4 kW and about 7 kW. Depositing of the metal composite layer 13 may take about 5 min to about 15 min. During depositing the metal composite layer 13, a first metal layer 131 can be deposited on the plastic substrate 11 when the plastic substrate 11 passes through the first target 22, and a second metal layer 133 can be deposited on the plastic substrate 11 when the plastic substrate 11 passes through the second target 23. Thus, a plurality of alternating first metal layers 131 and second layers 133 are formed on the plastic substrate 11. The metal composite layer 13 has a thickness of about 0.2 μm to about 0.5 μm.

A protective layer 15 is deposited on the metal composite layer 13. The protective layer 15 is stainless steel layer, Ni layer or Cr layer. The sputtering coating chamber 20 is maintained at a room temperature. Argon may be used as a working gas and is injected into the sputtering coating chamber 20 at a flow rate from about 150 sccm to about 240 sccm. The third targets 24 in the sputtering coating chamber 20 are evaporated at a power between about 8 kW and about 15 kW. Depositing of the protective layer 15 may take about 5 min to about 15 min. The protective layer 15 has a thickness of about 0.1 μm to about 0.4 μm.

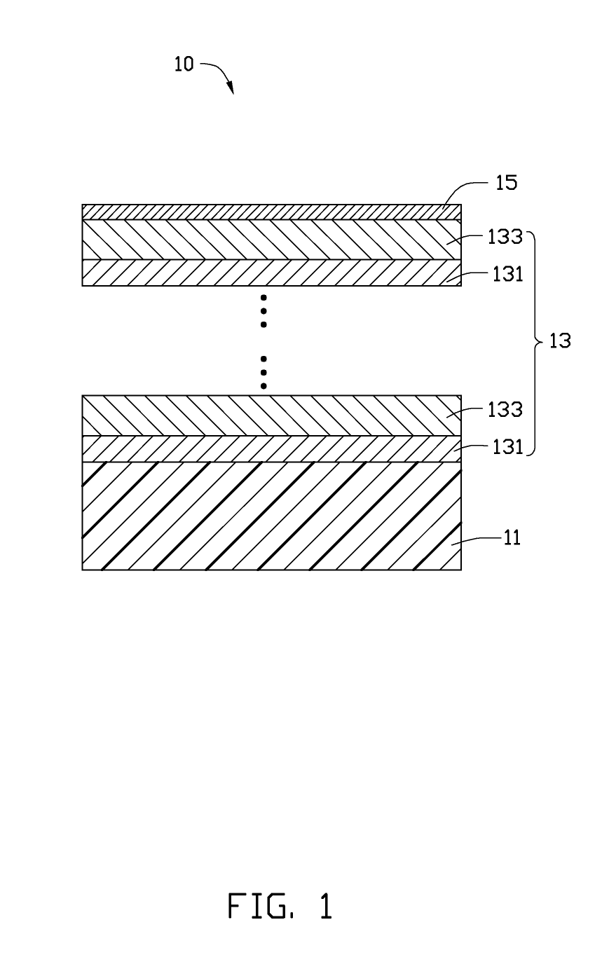

FIG. 1 shows a cross-section of an exemplary product 10 made by the electromagnetic shielding method described above. The product 10 includes the plastic substrate 11, the metal composite layer 13 and the protective coating 15 formed on the plastic substrate 11 in that order. The electromagnetic shielding effectiveness is about 30-60 decibels (dB).

The plastic substrate 11 may be housing of mobile phone, PDA, notebook computer, portable music player, GPS navigator, or digital camera.

The metal composite layer 13 includes a plurality of first metal layers 131 and a plurality of second metal layers 133. The first metal layers 131 and the second metal layers 133 are same in number and alternate with each other to form the metal composite layer 13. The first metal layer 131 is Cu layer, Ag layer or Li layer. The second metal layer 133 is Ni layer. The first metal layer is directly formed on the plastic substrate 11. The outermost layer is the first metal layer 131 or the second metal layer 133. The metal composite layer 13 has a thickness of about 0.2 μm to about 0.5 μm.

The protective layer 15 can protect the metal composite layer from scratches. The protective layer 15 has a thickness of about 0.1 μm to about 0.4 μm.

Cu, Ag or Li has high electrical conductivity, and Ni has high magnetic conductivity, which can improve the effectiveness of absorbing electromagnetic of the metal composite layer 13. Furthermore, the first metal layer 131 and the second metal layer 133 with different impedance to the electromagnetic waves, the impedance discontinuity will cause the reflection loss of electromagnetic waves between each first metal layer 131 and each second metal layer 133. Thus, the cumulative reflection loss of electromagnetic waves between a plurality of first metal layers 131 and a plurality of second metal layers 133 can greatly increase the amount of the loss of electromagnetic waves. Thus, the product 10 has excellence electromagnetic shielding effectiveness.

### EXAMPLES

Experimental examples of the present disclosure are described as follows.

### Example 1

Sandblasting process: using “80#” type ceramic sand and the sandblasting pressure was set at about 1.2 MPa.

Depositing the metal composite layer 13: the vacuum level inside the sputtering coating chamber 20 was set at about 4×10⁻³ Pa; the sputtering coating chamber 20 was at room temperature; the flux rate of argon gas was about 180 sccm; about 10 kW of power was applied to the first targets 22 and about 5 kW of power was applied to the second targets 23; sputtering of the metal composite 13 take about 6 min. The first targets 22 were made of Cu; the second targets 23 were made of Ni. The metal composite layer 13 has a thickness of about 0.2 μm.

Depositing the protective layer 15: about 8 kW of power was applied to the third targets 24; the flux rate of argon gas was 180 sccm; the sputtering coating chamber 20 was at room temperature; sputtering of the protective layer 15 take about 5 min. The third targets 25 were stainless steel. The protective layer 15 has a thickness of about 0.1 μm.

### Example 2

Sandblasting process: using “80#” type ceramic sand and the sandblasting pressure was set at about 1 MPa.

Depositing the metal composite layer 13: the vacuum level inside the sputtering coating chamber 20 was set to about 6×10⁻³ Pa; the sputtering coating chamber 20 was at room temperature; the flux rate of argon gas was about 200 sccm; about 12 kW of power was applied to the first targets 22 and about 6 kW of power was applied to the second targets 23; sputtering of the metal composite 13 take about 10 min. The first targets 22 were Ag; the second targets 23 were Ni. The metal composite layer 13 has a thickness of about 0.4 μm.

Depositing the protective layer 15: about 10 kW of power was applied to the third targets 24; the flux rate of argon gas was about 200 sccm; the sputtering coating chamber 20 was at room temperature; sputtering of the protective layer 15 take about 10 min. The third targets 25 were made of stainless steel. The protective layer 15 has a thickness of 0.3 μm.

### Comparison Example

Sandblasting process: using “80#” type ceramic sand and the sandblasting pressure was set at about 1 MPa.

Depositing the Cu layer: the vacuum level inside the sputtering coating chamber 20 was set to about 6×10⁻³ Pa; the sputtering coating chamber 20 was at room temperature; the flux rate of argon gas was about 200 sccm; about 6 kW of power was applied to the first targets 22; sputtering of the metal composite 13 take about 8 min. The first targets 22 were made of Cu. The Cu layer has a thickness of about 0.5 μm.

Depositing the protective layer 15: about 10 kW of power was applied to the third targets 24; the flux rate of argon gas was about 200 sccm; the sputtering coating chamber 20 was at room temperature; sputtering of the protective layer 15 take about 10 min. The third targets 25 were made of stainless steel. The protective layer 15 has a thickness of about 0.3 μm.

### Results of the Above Examples

The electromagnetic shielding effectiveness of the samples created by above examples was tested by an “E5071C” type electromagnetic shielding test apparatus sold by Agilent Company. During the frequency of about 100 KHz-4.5 GHz, the sample created by example 1, the sample created by example 2, and the sample created by comparison example have a shielding effectiveness of about 55 dB, about 60 dB, and about 20 dB respectively. The result shows that the samples created by example 1 and example 2 have good shielding effectiveness.

It is to be understood, however, that even through numerous characteristics and advantages of the exemplary disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A product, comprising:
a plastic substrate; and
a metal composite layer deposited on the plastic substrate, wherein the metal composite layer comprises a plurality of first metal layers and a plurality of second metal layers, the first metal layers and the second metal layers are alternate with each other, the first metal layer is Cu layer, Ag layer or Li layer; the second metal layer is Ni layer.

2. The product as claimed in claim 1, wherein the first metal layer is directly formed on the plastic substrate.

3. The product as claimed in claim 1, wherein the outermost layer of the metal composite layer is the first metal layer or the second metal layer.

4. The product as claimed in claim 1, wherein the metal composite layer has a thickness of about 0.2 μm to about 0.5 μm.

5. The product as claimed in claim 1, wherein further comprising a protective layer formed the metal composite layer.

6. The product as claimed in claim 5, wherein the protective layer is stainless steel layer, Ni layer or Cr layer.

7. The product as claimed in claim 5, wherein the protective layer has a thickness of about 0.1 μm to about 0.4 μm.

8. The product as claimed in claim 1, wherein the electromagnetic shielding effectiveness is about 30-60 dB.

9. A method for manufacturing a product comprising steps of:
providing a plastic substrate; and
depositing a metal composite layer on the plastic substrate by magnetron sputtering, wherein the metal composite layer comprises a plurality of first metal layers and a plurality of second metal layers, the first metal layers and the second metal layers are alternate with each other, the first metal layer is Cu layer, Ag layer or Li layer; the second metal layer is Ni layer.

10. The method of claim 9, wherein during deposition of the metal composite layer on the plastic substrate, the plastic substrate is retained in a sputtering coating chamber of a vacuum sputtering coating machine, the vacuum sputtering coating machine comprises first targets and second targets, the first targets are made of material selected from one of Cu, Ag and Li; the second targets are made of Ni; the sputtering coating chamber is maintained at a room temperature; sputtering the first targets and the second targets at the same time, the first targets are evaporated at a power between about 8 kW and about 12 kW, the second targets are evaporated at a power between about 4 kW and about 7 kW; depositing of the metal composite layer on the plastic substrate take from about 5 minutes and about 15 minutes.

11. The method of claim 9, wherein further including a step of depositing a protective layer on the metal composite layer by magnetron sputtering, the protective layer is stainless steel layer, Ni layer or Cr layer; wherein during depositing the protective layer, the temperature in the vacuum chamber is room temperature, argon used as a working gas and have a flow rate from about 150 sccm to about 240 sccm; the third targets is evaporated at a power from about 8 kW to about 15 kW; the third targets are made of material selected from one of stainless steel, Ni and Cr; depositing of the protective layer on the metal composite layer take from about 5 minutes and about 15 minutes.

12. The method of claim 9, wherein further includes a step of sandblasting the plastic substrate to improve the bonding force between the plastic substrate and the metal composite layer will form on the plastic substrate.

13. The method of claim 12, wherein during the sandblasting process, uses “80#” type ceramic sand and the sandblasting pressure is set about 0.8 MPa to about 1.2 MPa.
